(19) United States
(12) Patent Application Publication
(10) Pub. No.: US 2008/0237678 A1
(43) Pub. Date: Oct. 2, 2008

(54) On-chip memory cell and method of manufacturing same

(76) Inventors: Suman Datta, Beaverton, OR (US); Jack T. Kavalieros, Portland, OR (US); Brian S. Doyle, Portland, OR (US); Dinesh Somasekhar, Portland, OR (US); Ali Keshavarzi, Portland, OR (US)

Correspondence Address: INTEL CORPORATION;c/o INTELLEVATE, LLC, P.O. BOX 52050, MINNEAPOLIS, MN, 55402, US

(21) Appl. No.: 11/729,192

(22) Filed: Mar. 27, 2007

(51) Int. Cl. H01L 27/108; H01L 21/336

(52) U.S. Cl. 257/313; 438/283; 257/E27.084; 257/E21.409

(57) ABSTRACT

An on-chip memory cell comprises a tri-gate access transistor (145) and a tri-gate capacitor (155). The on-chip memory cell may be an embedded DRAM on a three-dimensional tri-gate transistor and capacitor structures which is fully compatible with existing tri-gate logic transistor fabrication process. Embodiments of the invention use the high fin aspect ratio and inherently superior surface area of the tri-gate transistors to replace the “trench” capacitor in a commodity DRAM with an inversion mode tri-gate capacitor. The tall sidewalls of the tri-gate transistor provide large enough surface area to provide storage capacitance in a small cell area.

### FIELD OF THE INVENTION

The disclosed embodiments of the invention relate generally to memory cells, and relate more particularly to tri-gate based embedded DRAM cells.

### BACKGROUND OF THE INVENTION

With technology scaling and increasing transistor count every generation, the microprocessor world is poised to migrate to a many-core platform. This implies having four or more microprocessor cores each with their own dedicated lower level (L1/L2) cache integrated on-chip on the same die. This improves parallelism and enhances overall microprocessor performance without dissipating excessive power. However, in the often encountered scenario of a “cache miss,” the physical memory sitting off-chip needs to be accessed, and this results in both power and performance loss. Thus, there is a great need for on-chip, large size, dense physical memory which is shared by many cores. Register file cells and 6 transistor (6T) static random access memory (SRAM) cache is the most common embedded memory element used with logic transistors to be operated at the same speed. Typical L2 cache offered in commonly available microprocessor products ranges from 2-4 megabytes. Still there is further need for a high bandwidth, high density on-chip memory block to improve performance, such as embedded dynamic random access memory (DRAM).

### BRIEF DESCRIPTION OF THE DRAWINGS

The disclosed embodiments will be better understood from a reading of the following detailed description, taken in conjunction with the accompanying figures in the drawings in which:

FIG. 1 is a perspective view of an on-chip memory cell according to an embodiment of the invention;

FIG. 2 is a graph showing charge capacitance per unit area and gate leakage current per unit area for an embodiment of the invention; and

FIG. 3 is a flowchart illustrating a method of manufacturing an on-chip memory cell according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner.

### DETAILED DESCRIPTION OF THE DRAWINGS

In one embodiment of the invention, an on-chip memory cell comprises a tri-gate access transistor and a tri-gate capacitor. The on-chip memory cell may be an embedded DRAM on a three-dimensional tri-gate transistor and capacitor structures which is fully compatible with an existing tri-gate logic transistor fabrication process. Embodiments of the invention use the high fin aspect ratio and inherently superior surface area of the tri-gate transistors to replace the “trench” capacitor in a commodity DRAM with an inversion mode tri-gate capacitor. The tall sidewalls of the tri-gate transistor provide large enough surface area to provide storage capacitance in a small cell area, thus addressing the need to integrate a large, high-density 1T-1C DRAM memory element with a logic technology process.

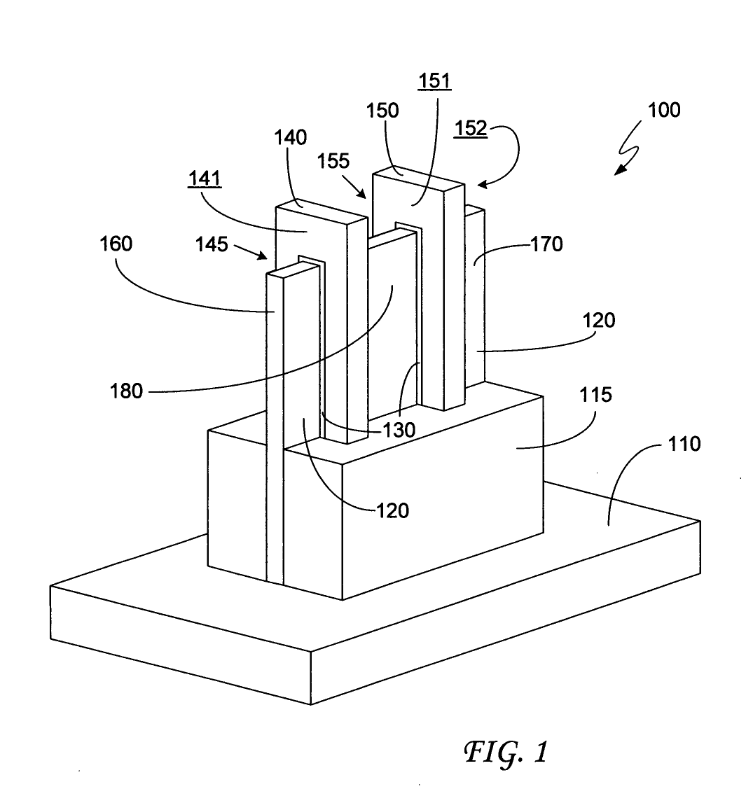

Referring now to the figures, FIG. 1 is a perspective view of an on-chip memory cell 100 according to an embodiment of the invention. As illustrated in FIG. 1, on-chip memory cell 100 comprises a substrate 110, an electrically insulating layer 115 over substrate 110, a semiconducting fin 120 over substrate 110 and electrically insulating layer 115, a metal layer (not shown) over at least a portion of semiconducting fin 120, and a gate dielectric layer 130 over the metal layer. A gate electrode 140 and a gate electrode 150 straddle semiconducting fin 120 over gate dielectric layer 130. On-chip memory cell 100 further comprises a drain region 160 in semiconducting fin 120 at a side 141 of gate electrode 140, a drain region 170 in semiconducting fin 120 at a side 152 of gate electrode 150, and a source region 180 in semiconducting fin 120 at a side 151 of gate electrode 150 and between gate electrode 140 and gate electrode 150. In one embodiment, drain region 160 is electrically connected to a column bit line and gate electrode 140 is electrically connected to a row word line of on-chip memory cell 100.

As illustrated in FIG. 1, on-chip memory cell 100 comprises a single fin (semiconducting fin 120) with two parallel gates (gate electrodes 140 and 150). Where gate electrode 140 wraps around semiconducting fin 120, an access transistor of the DRAM cell is formed. The second device forms a storage capacitor where gate electrode 150 wraps around all three exposed sides of semiconducting fin 120. The transfer node (i.e., the “storage node”—the physical region where the charge is stored) is the common source region 180 which is shared by the tri-gate access transistor and the tri-gate inversion mode capacitor. An advantage of this configuration is that the gate capacitance (which is the storage capacitance) can be maximized by increasing a height of semiconducting fin 120 (globally or selectively) of the storage device. Selective height increase is only possible on a bulk silicon (as opposed to a silicon-on-insulator (SOI) substrate). Accordingly, in one embodiment substrate 110 is a bulk silicon substrate and semiconducting fin 120 has a first height at gate electrode 140 and a second height at gate electrode 150. In a particular embodiment, the second height is greater than the first height in order to maximize the storage capacitance.

In one embodiment, semiconducting fin 120 is made of silicon or the like. In the same or another embodiment, electrically insulating layer 115 can be a shallow trench isolation layer comprising silicon dioxide or the like. In the same or another embodiment, gate dielectric layer 130 comprises a high-k dielectric material such as hafnium oxide, zirconium oxide, PZT, or another material having a dielectric constant (k) of approximately 10 or greater. In the same or another embodiment, gate electrodes 140 and 150 can comprise polysilicon, metal, or another suitable material. In that regard, polysilicon gates suffer from depletion effects that do not affect metal gates, and therefore metal gates may be superior in at least some embodiments of the invention.

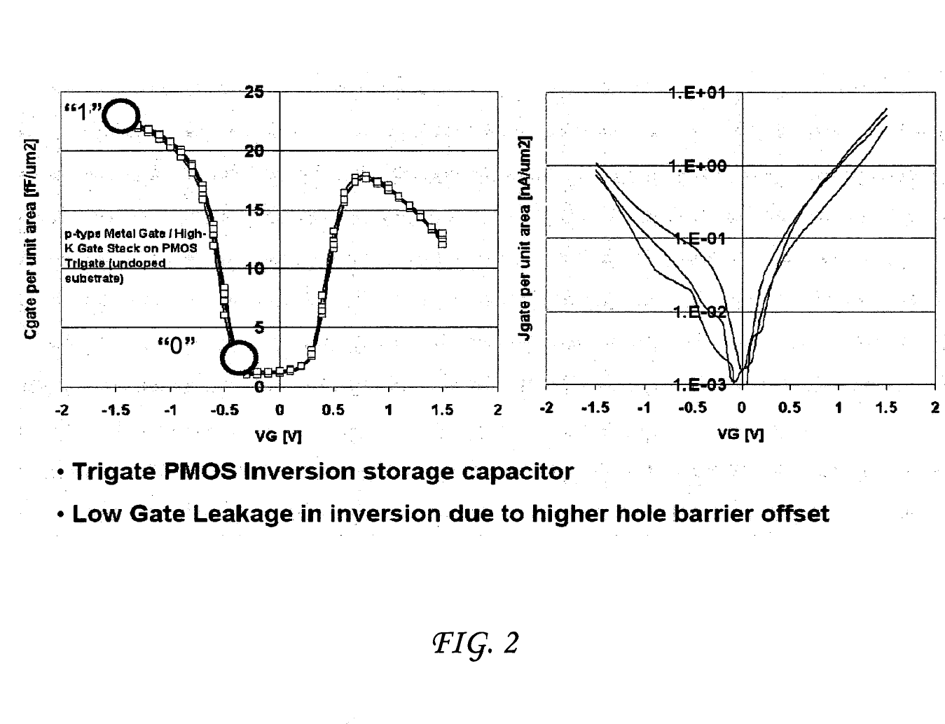

As an example, on-chip memory cell 100 can be a 1T-1C DRAM cell, with gate electrode 140 comprising an access transistor of the DRAM cell and gate electrode 150 comprising a capacitor of the DRAM cell. As a further example, gate electrode 140 can form a part of a tri-gate access transistor 145 and gate electrode 150 can form a part of a tri-gate storage capacitor 155 (which may be an inversion mode tri-gate capacitor or an accumulation mode tri-gate capacitor). The combination of a high-k/metal gate stack and a tri-gate tall fin architecture enables the creation of a very low leakage storage capacitor. As an example, in a particular embodiment an inversion mode tri-gate capacitor has an inversion charge capacitance of at least approximately 23 fF over a unit area and a gate leakage current of less than approximately 1 nA, as shown in FIG. 2.

More specifically, FIG. 2 shows the experimental inversion capacitance (normalized to the tri-gate peripheral area) data obtained on a typical tri-gate device. Also shown is the area-normalized gate leakage current obtained from the same storage element. Gate leakage can be a very important metric since, in at least one embodiment, it will decide or affect the retention time of the DRAM memory element. As mentioned above, FIG. 2 demonstrates a capacitance of 23 fF of inversion charge capacitance over a unit area, with a corresponding gate leakage current of less than 1 nano-Amp (nA). This leakage current under “hold” condition will cause 100 mV degradation in capacitance voltage in 23*0.1/1=2.3 microsecond. In order to further improve the refresh time to the millisecond domain, the gate leakage needs to be lowered to the pico-Amp (pA) range without degrading capacitance. This can be achieved by using dielectrics with high dielectric constants (such as PZT (perovskites)).

Referring again to FIG. 1, gate electrodes 140 and 150 straddle semiconducting fin 120, which in one embodiment has an aspect ratio of at least 2:1. The gate capacitance (or storage capacitance) of storage capacitor 155 is proportional to its surface area, and such surface area increases (as desired) with increasing surface area of semiconducting fin 120. With an aspect ration of 2:1 or greater semiconducting fin 120 has a relatively large surface area that increases the storage capacitance as set forth above. In one embodiment, semiconducting fin 120 has a first aspect ratio at gate electrode 140 and a second aspect ratio at gate electrode 150. In a particular embodiment, the second aspect ratio is greater than the first aspect ratio. In another particular embodiment, the first aspect ratio is between approximately 2:1 and approximately 5:1, and the second aspect ratio is at least approximately 4:1.

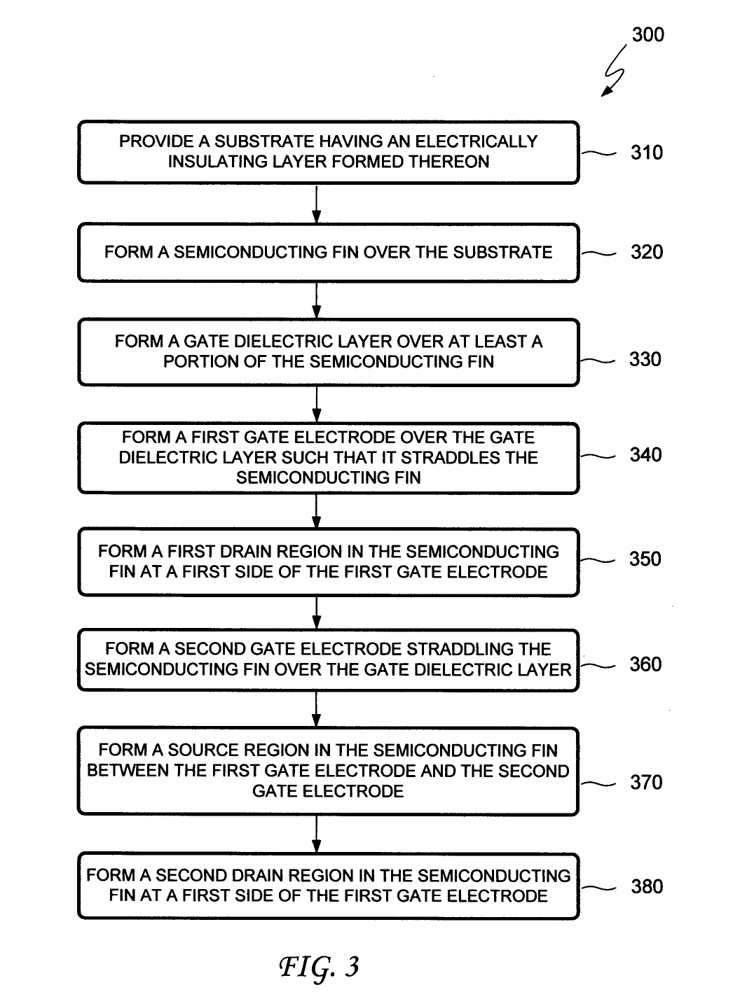

FIG. 3 is a flowchart illustrating a method 300 of manufacturing an on-chip memory cell according to an embodiment of the invention. A step 310 of method 300 is to provide a substrate having an electrically insulating layer formed thereon. As an example, the substrate can be similar to substrate 110 and the electrically insulating layer can be similar to electrically insulating layer 115, both of which are shown in FIG. 1.

A step 320 of method 300 is to form a semiconducting fin over the substrate. As an example, the semiconducting fin can be similar to semiconducting fin 120 that is shown in FIG. 1. The fin height is set by selecting a depth of a wet recess etch of the silicon dioxide or other electrically insulating layer.

A step 330 of method 300 is to form a gate dielectric layer over at least a portion of the semiconducting fin. In at least one embodiment step 330 constitutes a very conformal deposition of gate dielectric on all three exposed sides of the semiconducting fin. As an example, the gate dielectric layer can be similar to gate dielectric layer 130 that is shown in FIG. 1. In one embodiment, step 330 comprises forming a high-k material and a metal layer over at least the portion of the semiconducting fin. As an example, the metal layer can be similar to the metal layers discussed above in connection with FIG. 1.

A step 340 of method 300 is to form a first gate electrode over the gate dielectric layer such that it straddles the semiconducting fin. As an example, the first gate electrode can be similar to gate electrode 140 that is shown in FIG. 1.

A step 350 of method 300 is to form a first drain region in the semiconducting fin at a first side of the first gate electrode. As an example, the first drain region can be similar to drain region 160 that is shown in FIG. 1.

A step 360 of method 300 is to form a second gate electrode straddling the semiconducting fin over the gate dielectric layer. As an example, the second gate electrode can be similar to gate electrode 150 that is shown in FIG. 1. In at least one embodiment, step 360 is performed simultaneously with step 340 such that both the first and second gate electrodes are formed substantially at the same time.

A step 370 of method 300 is to form a source region in the semiconducting fin between the first gate electrode and the second gate electrode. As an example, the source region can be similar to source region 180 that is shown in FIG. 1.

A step 380 of method 300 is to form a second drain region in the semiconducting fin at a first side of the first gate electrode. As an example, the second drain region can be similar to drain region 170 that is shown in FIG. 1.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the on-chip memory cell and related methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. An on-chip memory cell comprising:
a tri-gate access transistor; and
a tri-gate capacitor.

2. The on-chip memory cell of claim 1 wherein:
the tri-gate capacitor is one of an inversion mode tri-gate capacitor and an accumulation mode tri-gate capacitor.

3. The on-chip memory cell of claim 2 wherein:
the inversion mode tri-gate capacitor has an inversion charge capacitance of at least approximately 23 fF over a unit area and a gate leakage current of less than approximately 1 nA.

4. The on-chip memory cell of claim 1 wherein:
the tri-gate access transistor and the tri-gate capacitor straddle a silicon fin that has an aspect ratio of at least 2:1.

5. The on-chip memory cell of claim 4 wherein:
the silicon fin has a first aspect ratio at the tri-gate access transistor and a second aspect ratio at the tri-gate capacitor.

6. The on-chip memory cell of claim 5 wherein:
the first aspect ratio is between approximately 2:1 and approximately 5:1; and
the second aspect ratio is at least approximately 4:1.

7. The on-chip memory cell of claim 4 wherein:
the tri-gate access transistor further comprises a gate dielectric layer over the silicon fin; and
the gate dielectric layer comprises a high-k dielectric material.

8. An on-chip memory cell comprising:
a substrate;
a semiconducting fin over the substrate;
a gate dielectric layer over at least a portion of the semiconducting fin;
a first gate electrode straddling the semiconducting fin over the gate dielectric layer;
a first drain region in the semiconducting fin at a first side of the first gate electrode;
a second gate electrode straddling the semiconducting fin over the gate dielectric layer;
a source region in the semiconducting fin at a first side of the second gate electrode and between the first gate electrode and the second gate electrode; and
a second drain region in the semiconducting fin at a second side of the second gate electrode.

9. The on-chip memory cell of claim 8 wherein:
the on-chip memory cell is a DRAM cell;
the first gate electrode comprises an access transistor of the DRAM cell; and
the second gate electrode comprises a capacitor of the DRAM cell.

10. The on-chip memory cell of claim 9 wherein:
the access transistor of the DRAM cell comprises a tri-gate access transistor; and
the capacitor of the DRAM cell comprises a tri-gate storage capacitor.

11. The on-chip memory cell of claim 10 wherein:
the tri-gate storage capacitor is an inversion mode capacitor.

12. The on-chip memory cell of claim 11 wherein:
the tri-gate storage capacitor has an inversion charge capacitance of at least approximately 23 fF over a unit area and a gate leakage current of less than approximately 1 nA.

13. The on-chip memory cell of claim 8 wherein:
the gate dielectric layer comprises a high-k dielectric material.

14. The on-chip memory cell of claim 8 wherein:
the semiconducting fin comprises silicon; and
the semiconducting fin has an aspect ratio of at least 2:1.

15. The on-chip memory cell of claim 14 wherein:
the substrate is a bulk silicon substrate; and
the semiconducting fin has a first height at the first gate electrode and a second height at the second gate electrode.

16. The on-chip memory cell of claim 15 wherein:
the second height is greater than the first height.

17. The on-chip memory cell of claim 8 wherein:
the first drain region is electrically connected to a column bit line of the on-chip memory cell; and
the first gate electrode is electrically connected to a row word line of the on-chip memory cell.

18. A method of manufacturing an on-chip memory cell, the method comprising:
providing a substrate having an electrically insulating layer formed thereon;
forming a semiconducting fin over the substrate and the electrically insulating layer;
forming a gate dielectric layer over at least a portion of the semiconducting fin;
forming a first gate electrode over the gate dielectric layer such that it straddles the semiconducting fin;
forming a first drain region in the semiconducting fin at a first side of the first gate electrode;
forming a second gate electrode straddling the semiconducting fin over the gate dielectric layer;
forming a source region in the semiconducting fin between the first gate electrode and the second gate electrode; and
forming a second drain region in the semiconducting fin at a first side of the first gate electrode.

19. The method of claim 18 wherein:
forming the gate dielectric layer comprises forming a high-k material and a metal layer over at least the portion of the semiconducting fin.

20. The method of claim 18 wherein:
forming the first gate electrode and forming the second gate electrode comprise forming a first metal gate electrode and forming a second metal gate electrode.
